(19) United States
(12) Patent Application Publication
(10) Pub. No.: US 2023/0371377 A1
(43) Pub. Date: Nov. 16, 2023

(54) DEVICES AND METHODS FOR HANDLING A FLUID WORKING MEDIUM

(71) Applicant: Thilo Ittner, Wangen im Allgäu (DE)

(72) Inventor: Thilo Ittner, Wangen im Allgäu (DE)

(21) Appl. No.: 18/196,275

(22) Filed: May 11, 2023

(30) Foreign Application Priority Data
May 13, 2022 (DE) 102022112016.3
Jun. 8, 2022 (DE) 102022114439.9

(51) Int. Cl. H10N 10/00; F04C 2/344

(52) U.S. Cl. CPC H10N 10/00; F04C 2/3441

(57) ABSTRACT

A device includes at least one volume that comprises a liquid quantity of a liquid and a partial volume with a working medium. The device further includes multiple volume limiting elements which limit the at least one volume and which are configured such that one or more passages allow outflow of a maximum of a predetermined partial quantity of the liquid quantity during one or more of a compression period, an expansion period, or a displacement period. The liquid quantity performs a rotation about an axis of rotation. The multiple volume limiting elements are configured to prevent an annular flow of the liquid quantity about the axis of rotation. The at least one volume is changeable in terms of its overall size by displacement of at least one of the volume limiting elements.

### RELATED APPLICATIONS

This application claims the benefit under 35 U.S.C. § 119(a) of German Patent Application No. 102022112016.3, filed May 13, 2022, and of German Patent Application No. 102022114439.9, filed Jun. 8, 2022, both of which are incorporated by reference herein.

### TECHNICAL FIELD

The present disclosure relates to a device for the compression, expansion, volume change, and/or displacement of a fluid working medium, a thermoelectric converter, and a computer-controlled or electronically controlled method.

### BACKGROUND

There are already devices for the compression or expansion of gases in which this occurs in part or largely isothermally. An example is that of the compression or expansion chambers of flat-plate Stirling engines. Another example is that of liquid ring pumps, where a gas is thermally coupled to a liquid during the expansion or compression. Flat-plate Stirling engines have the disadvantage that the heat transfer in the compression or expansion chamber from or to the working gas takes place via a heat exchanger, for which a higher temperature gradient is required than when the working gas (i.e. the gas to be compressed or expanded) would be thermally coupled directly to the medium from which or to which the heat is to be extracted or supplied (e.g. a liquid such as water as the heat transfer medium). In addition, flat-plate Stirling engines have a comparatively complex structure and only achieve low power densities. Liquid ring pumps have such a direct coupling of the working gas to a liquid as the heat transfer medium. However, they have the drawback that strong liquid flows take place during operation which are caused by the eccentric rotation of the impeller as well as by the pressure changes in the gas to be compressed or expanded. Energy from the drive of the liquid ring pump must be expended for these flows, which ultimately does not benefit the function of compression or expansion of the working gas but leads to the liquid being heated as a loss of flow and therefore represents a power loss. Therefore, the degrees of efficiency of liquid ring pumps are typically significantly lower than those of other pumps or devices for the compression or expansion of gases.

To convert heat/cold or quantities of heat into mechanical/electrical energy or vice versa, machines are often used today that operate according to the Clausius-Rankine process, the Ericsson process, or the Stirling process. A working medium is there alternately compressed at a certain temperature and expanded at a certain other temperature, giving off or absorbing quantities of heat. In particular, a phase transition of the medium between a liquid and gaseous state can also occur in the Clausius-Rankine process, the working medium in the Stirling process and in the Ericsson process typically remains gaseous, although there are also embodiments with phase changes at least in part. The Vuilleumier process is also used to convert quantities of heat at certain temperatures into quantities of heat at certain other temperatures. Other operating principles such as adsorption or absorption heat pumps are also part of prior art.

Stirling engines and machines that implement the Clausius-Rankine process or the Ericsson process today have the drawback that their production costs are often not economical in relation to the quantities of energy that can be converted with them. Furthermore, they typically have degrees of efficiency that are far worse due to the technical implementation than the ideal Carnot degree of efficiency for heat engines or heat pumps, respectively. This is due to the following reasons, among others:

The expansion and/or compression of the working medium used takes place largely adiabatically and not isothermally

The heat exchanger surfaces are too small or the coupling of the quantities of heat supplied to/dissipated from the working medium is not sufficient to ensure a heat transfer that heats/cools the working gas far enough during the time available.

Dead spaces exist in Stirling engines so that the working gas is not completely disposed in the intended expansion or compression volumes during the expansion or compression.

Mechanical friction losses or flow-mechanical friction losses arise during operation.

Patent EP 2 657 497 B1 describes a thermoelectric converter that largely solves the first three of the above problems by having heat exchangers that periodically immerse in liquids. These liquids are coupled to external heat sources/sinks. The advantage of this is that this thermoelectric converter manages with minimal dead spaces, that the position of the heat exchangers in the compression/expansion chambers means that almost isothermal compression/expansion takes place, and that very good heat transfer is ensured between the external heat sources/sinks and the working medium due to the comparatively large heat exchanger surfaces and due to periodic immersion into the liquid. However, this thermoelectric converter is limited in terms of its performance or power density, respectively: It can be operated at a maximum operating frequency at which the periodic immersion of the heat exchanger surfaces into the liquid does not result in the liquid being partially carried along when the heat exchanger surfaces are pulled out and therefore “splashes around” in an uncoordinated manner in the workspace This maximum operating frequency is primarily determined by the weight force of the liquid and by the amplitude of the motion of the volume change elements and heat exchanger surfaces.

The device from DE 10 2018 212 088 B3 makes it possible to significantly increase the maximum operating frequency and thereby the power or power density, respectively. It operates according to a similar principle in which volume limiting elements and possible additional heat exchanger surfaces are periodically immersed into a liquid, where this liquid performs a rotational motion and is thereby prevented from “squirting out” due to centrifugal forces, even at higher operating frequencies, since the centrifugal forces arising are significantly higher than the respective weight force of the liquid. However, there is a strong liquid flow in the device described in DE 10 2018 212 088 B3 which leads to high friction losses in terms of fluid mechanics. This is mainly caused by the displacement of liquid from the regions between the vane blades or into these regions, respectively, which is caused, among other things, by changes in the pressure of the working medium. This flow can take place unhindered since the liquid is not prevented from doing so by limiting elements. Mechanical energy from the rotational motion of the rotors is expended for this flow, which is ultimately converted into frictional heat within the liquid and therefore entails a high thermal dissipation loss.

### BRIEF DESCRIPTION OF THE FIGURES

The accompanying figures illustrate aspects and/or embodiments of the present disclosure by way of example for better understanding and for illustration purposes, where:

FIG. 1 shows a 3D view of a first embodiment of a thermodynamic converter,

FIG. 2 shows a longitudinal sectional view of the device of FIG. 1,

FIG. 3 shows a cross-sectional view (section A-A) through the first main chamber,

FIG. 4 shows a cross-sectional view (section B-B) through the second main chamber,

FIG. 5 shows a 3D view of the first rotor together with the connecting elements,

FIG. 6 shows an alternative embodiment of the first rotor with additional heat exchanger elements,

FIG. 7 shows a second embodiment of a thermodynamic converter,

FIG. 8 shows a first cross-sectional view (section A-A) through the first main chamber,

FIG. 9 shows a second cross-sectional view (section B-B) through the first main chamber,

FIG. 10 shows a three-dimensional view of the rotors together with the connecting elements that are permeable to gas,

FIG. 11 shows a longitudinal sectional view through a third embodiment of a thermodynamic converter,

FIG. 12 shows a first cross section (section A-A) through the first main chamber,

FIG. 13 shows second cross section (section B-B) through the second main chamber,

FIG. 14 shows a rotary piston of an alternative embodiment,

FIG. 15 shows the rotary piston of FIG. 14 in a three-dimensional view,

FIG. 16 shows a further embodiment of a thermodynamic converter, and

FIG. 17 shows a three-dimensional view of the reciprocating pistons, displacement piston, connecting elements, the eccentric, and the ball bearing.

### DETAILED DESCRIPTION

The present disclosure may provide a method and a thermoelectric converter which enable a largely isothermal compression or expansion of a working medium.

This present disclosure may provide device a thermoelectric converter, and a computer-controlled or electronically controlled method. Further embodiments are disclosed herein.

The present disclosure relates to a device for a largely isothermal compression or expansion of a working medium (typically gas or gas with liquid mist)—in contrast to the widespread largely adiabatic devices for gas compression or gas expansion such as piston compressors. In addition to the compression or expansion of the working medium, a phase transition of a component of the working medium from the gaseous to the liquid state or from the liquid to the gaseous state can also take place within the device. Due to the isothermal change of state of the gas, for example, a compression can be implemented that requires less mechanical or electrical energy than an adiabatic compression. The change in temperature that occurs during a compression or expansion of the working medium can therefore be compensated for very quickly in that the working medium gives off heat energy to the liquid or absorbs it therefrom and is thereby kept largely constant at a temperature that corresponds to that of the liquid. In other words, this means that the working medium can be compressed or expanded largely isothermally.

Such a largely isothermal change of state of a gas is particularly advantageous in the realization of thermodynamic cyclic processes such as the Stirling process, the Ericsson process or the Clausius-Rankine process, since higher degrees of efficiency can be obtained in this way than in the case of largely adiabatic changes of state. In these cycles, a working medium, which is at least in part or temporarily gaseous, runs through a thermodynamic cyclic process in which its pressure, temperature, volume, and other state variables change.

Therefore, some embodiments described herein can be used in a device/method for converting quantities of heat (heat source and heat sink with different temperatures) into mechanical/electrical energy or mechanical/electrical energy into heat and cold or quantities of heat at certain temperatures into quantities of heat at certain other temperatures.

The heat/cold can be coupled to this thermoelectric converter, for example, by way of liquids as heat transfer media. Its range of use can therefore be, for example, at temperatures and pressures at which these heat transfer media are liquid.

This application can replace conventional heat pumps, heat engines, or devices for converting (waste) heat or quantities of cold or heat with certain temperature differences into useful heat and/or useful cold.

The present disclosure can enable high degrees of efficiency. This is achieved firstly by the largely isothermal process control, secondly by an effective direct transfer of quantities of heat between the working medium used and the liquids as heat transfer media without an additional heat exchanger wall between the media, and thirdly by avoiding flow losses, as they arise with other largely isothermal devices for the compression or expansion of a gas (e.g. liquid ring pumps), and through the usability of small temperature differences to drive the device or through the possibility of being able to efficiently generate even small temperature differences when operating as a heat pump. This is possible due to the direct coupling of the working medium that is used in the engine to the liquid as a heat transfer medium without the detour through a heat exchanger.

Furthermore, low wear and a comparatively simple and a cost-effective structure can be implemented by the present disclosure.

Alternatively, the isothermal change of state can also be used in other applications in which a largely isothermal compression or expansion of a gas or a fluid containing gas is advantageous, e.g. as a vacuum pump, as a gas compressor, for the production of compressed air, compression and expansion devices for compressed air energy storage, expansion device for the conversion of gas pressure into mechanical/electrical energy, etc. Since a phase transition of components of the working gas or the liquid used can also take place in the compression and expansion device, it is also suitable for applications such as for liquefying gases (e.g. natural gas, nitrogen) or drying gases (e.g. air).

The present disclosure relates to a device for the compression, expansion, volume change, and/or displacement of a fluid working medium which consists of gas at least in part. The device comprises at least one volume which comprises a liquid quantity of a liquid and a partial volume with a working medium, and volume limiting elements which limit the volume and are configured such that one or more passages allow the outflow of a maximum of a predetermined partial quantity of the liquid quantity during a compression, expansion, or displacement period. During the compression, expansion, or displacement period, the liquid quantity performs a rotation about an axis of rotation. The volume limiting elements are additionally configured such as to prevent an annular flow of the liquid quantity about the axis of rotation. During the compression, expansion, or displacement period, the volume can be changed in terms of its overall size by the displacement of at least one of the volume limiting elements.

The volume limiting element can limit the volume except for the one or more passages (for example, gaps or openings for transporting the working medium or the liquid in or out). The gaps or openings can be dimensioned such or be connected to other volumes such that, for example, only a very small pressure loss is caused thereby during a compression or expansion period and that the liquid flows out of the volume or flows into the volume through these gaps or openings at a maximum of the predetermined partial amount (the predetermined partial amount can be 5% or 10% or 15% of the liquid quantity in the volume). The direct contact of the working medium with the liquid can ensure that the working medium is very effectively thermally coupled to the liquid: quantities of heat do not first have to be transferred from the liquid to a heat exchanger wall and only then be transferred to the working medium or vice versa. The change in temperature that occurs during the compression or expansion of the working medium can therefore be compensated for very quickly in that the working medium gives off heat energy to the liquid or absorbs it therefrom and is thereby kept largely constant at a temperature that corresponds to that of the liquid. In other words, this means that the working medium can be compressed or expanded largely isothermally. The liquid has a function as a “heat transfer medium” in that small quantities of it can escape from the volume through small openings in order to transport the heat or cold that has arisen out of the volume and to be able to use it outside of the device or to transfer it to a heat reservoir. Liquid can also enter the volume through a further or the same opening in order to transport heat or cold into the volume and to replace the liquid quantity that has escaped. These openings, like other openings or gaps, are dimensioned so small that the liquid can only flow through having a considerable flow resistance and only very slowly, i.e. the pressure in the volume changes only insignificantly and also only very small flow losses arise (friction losses due to the flow of the liquid).

For example, the device can be used for the largely isothermal compression of a gas in order to introduce the latter into a pressure vessel at overpressure. Mechanical or electrical energy must there be introduced into the device. The pressurized gas can then again be used in the opposite direction from the pressure vessel to be largely isothermally expanded by way of the device. This frees up mechanical or electrical energy that can be used elsewhere. Such a method can therefore be used as an energy storage in which the energy is stored in the form of the overpressure of the gas in the pressure vessel. In contrast to the use of devices that compress the gas largely adiabatically, high degrees of efficiency of such an energy storage can be obtained with the device presently described in such an application. In this embodiment, the gas can flow into and out of the device via pressure valves or openings which are open or closed depending on the position of the volume limiting elements.

Even when using the device presently described for generating compressed air or for compressing a gas or for generating a negative pressure or vacuum, high degrees of efficiency can be obtained due to the isothermal process control.

The device can comprise at least two of the volumes, each of which can comprise at least a partial volume of the working medium and liquid quantities, where the at least two volumes can each be limited by the volume limiting elements so that the liquid quantities of different volumes cannot mix to a maximum of the defined partial quantity.

The defined partial quantity can be 5% or 10% or 15%. The defined partial quantity can be 5% or 10% or 15% of the liquid quantity in the volume.

In contrast to conventional liquid ring pumps or in contrast to the device from DE 10 2018 212 088 B3, the volume limiting elements, which completely enclose the volume of the working medium and of the liquid except for small gaps or openings or exit/entry openings, prevent that the liquid is displaced or put into flow due to the changing pressure in the working medium, whereby energy would have to be expended which would ultimately be converted into frictional heat due to frictional losses in the flowing liquid and would therefore entail a thermal dissipation loss.

At least one first volume limiting element of the volume limiting elements can perform a rotational motion in a housing which can comprise the at least one volume, where an axis of rotation of the first volume limiting element can differ from a central axis of the housing, and/or the at least one first volume limiting element of the volume limiting elements can perform a first rotational motion, and at least one second volume limiting element can perform a second rotational motion, where a first axis of rotation of the first rotational motion and a second axis of rotation of the second rotational motion can differ from each other. The housing can be shaped like a circular cylinder or in some other way.

A first volume limiting element of the volume limiting elements can perform a rotational motion, where this first volume limiting element can comprise movable limiting elements which can periodically change their position relative to the first volume limiting element during the rotation of the first volume limiting element.

A first volume limiting element of the volume limiting elements can perform a motion which can comprise a rotational motion about a first axis and a rotational motion about a second axis.

At least a first volume limiting element of the volume limiting elements can comprise a piston or hollow piston which can perform a rotational motion that can be overlaid with a periodic translational motion.

In addition to the function as a heat transfer medium, the liquid can also fulfill a sealing function in that it prevents the working medium that is gaseous at least in part from escaping unintentionally from the volume through gaps or openings. Gaps or openings are therefore preferably surrounded by the liquid and not by the working medium.

The function of the device to expand, to compress, to change in volume or to displace the working medium is accomplished in that the volume limiting elements shift in their position relative to the liquid (or the liquid relative to the volume limiting elements) so that the partial volume that contains the working medium changes (this partial volume is limited, firstly, by the volume limiting elements and, secondly, by the liquid). The working medium is continuously in contact with the liquid and is accordingly thermally coupled thereto so that the compression, expansion, volume change or displacement takes place largely isothermally.

In order to prevent that the liquid is taken along with a motion relative to the volume limiting elements and would mix with the working medium in larger quantities or thus cause flow losses, the force that holds the liquid in its preferred position must be at least greater than the forces that would separate the liquid from its preferred position. In a device as described in EP 2 657 497 B1, this force is gravity. In this case, the gravitational acceleration must be at least greater than the maximum acceleration of the motion of the volume limiting elements relative to the liquid. In order to also be able to operate embodiments of the present disclosure at higher speeds (or working frequencies of the periodic motions) and therefore higher maximum accelerations of the relative motion of the volume change elements relative to the liquid, the liquid is set to perform a rotational motion. In addition to the force of gravity, additional significantly greater centrifugal forces act upon the liquid and keep it in its preferred position and prevent partial quantities of the liquid from being transported out by the motion of the volume limiting elements relative to the liquid, even at higher speeds of this relative motion.

At least one of the liquid quantities can move due to inertial forces or due to the motion of at least one of the volume limiting elements in the volume relative to others of the volume limiting elements and thereby change a size of at least one of the partial volumes.

The device can furthermore comprise heat transfer elements that periodically immerse into and out of the liquid in the liquid quantity disposed in the volume, where the heat transfer elements can comprise, for example, plates, meshes, and/or rods. The plates, nets, meshes, or rods can comprise, for example, metal.

A further advantage of the device presently described can be that the heat transfer between the working medium and the liquid takes place quickly and therefore effectively as compared to devices in which the heat is transferred via a conventional heat exchanger. The reason for this is that the working medium can complete its temperature equalization with the liquid directly at the interface between the working medium and the liquid, and the respective transfer of quantities of heat does not have to take place indirectly via the wall of a heat exchanger, in which quantities of heat are first effected from the working medium to the heat exchangers and in the second step from the heat exchanger to the liquid (or vice versa). This advantage can be enhanced by the heat transfer elements. During the immersion into the liquid, they are thermally coupled to the latter and largely take on the temperature of the liquid. While they are drawn out of the liquid, they are then thermally coupled to the working medium and temperature equalization takes place between them and the working medium. They thus increase the contact surface of the working medium with elements that have quasi the same temperature as the liquid so that the transfer of quantities of heat and hence the temperature equalization is accelerated. These heat transfer elements can additionally serve to reduce flows of the liquid quantities within the volume, for example, by arranging plates such that their surfaces are perpendicular to the direction of flow which they are intended to reduce. For example, plates can be arranged in the volumes such that their surfaces are arranged substantially perpendicular to the rotational motion of the liquid volumes about their axis of rotation in order to reduce the liquid volumes sloshing back and forth within their respective volumes.

A thermoelectric converter for converting quantities of heat into mechanical or electrical energy or for converting mechanical or electrical energy into heat/cold or for converting quantities of heat at first temperatures into quantities of heat at second temperatures comprises t least one device as described further above or further below.

A thermodynamic converter can be implemented with the thermoelectric converter, for example a Stirling process, an Ericsson process, a Clausius-Rankine process, or a Stirling process in which condensation and/or evaporation of a component of the working medium or the liquid can take place in addition to the compression and expansion or displacement of the working gas.

Thermodynamic cyclic processes in which a working medium undergoes a cyclical change in state (change in volume, pressure, temperature, state of aggregation, etc. in a certain sequence that is repeated cyclically) often have a high degree of efficiency if certain changes in state—for example compression or expansion processes, are largely isothermic rather than adiabatic. Examples of such cyclic processes are the Stirling process, the Vuilleumier process, the Ericsson process or the Clausius-Rankine process. Therefore, the device presently described can be suitable for realizing such a process with a high degree of efficiency.

The circular-cylindrically or differently shaped housing can be mounted to be freely rotatable about the central axis of the housing.

A computer-controlled or electronically controlled method of operating a thermoelectric converter as described above or below is provided.

The volume change elements can be controlled such that the working medium condenses at least in part during a compression and evaporates during a subsequent expansion. The working medium can also condense entirely during the compression.

The thermoelectric converter can convert mechanical/electrical energy into heat at certain temperatures (operating as a heat pump), or can convert heat at certain temperatures into electrical/mechanical energy (operating as a heat engine), or can convert quantities of heat at certain temperatures into quantities of heat at certain other temperatures (operating as in the combination of a heat pump with a heat engine or as in a Vuilleumier's machine). High degrees of efficiency can thus be obtained by using the device as described above or below, in addition, the efficient use or creation of even small temperature differences is possible due to the good and direct coupling of the working medium to the liquid as a heat transfer medium or heat transport medium, respectively.

The operation of such a process shall be explained below using the example of the Stirling process in its function as a heat pump. The working medium used in the process, presently a gas, is largely isothermally compressed in a first step in a first volume. It transfers quantities of heat to a first liquid quantity, which consequently heats up.

In a second step, the working medium is displaced from the partial volume that is disposed in the first volume together with this first liquid quantity. It flows through a (gas-tight) connection into a second volume containing a second liquid quantity. During this flow into the second volume, the working medium largely approaches the temperature of the liquid and the volume limiting elements of the second volume in that it dissipates quantities of heat to the wall of the connection or absorbs it therefrom. This temperature equalization of the working medium during the change from one volume to the other, which is important for obtaining a good degree of efficiency, can be improved if a so-called regenerator is used in the connection which has the largest possible surface region with which the working medium can be in contact (and thereby in thermal coupling) when flowing through. When the working medium flows through the regenerator, the former dissipates quantities of heat in the one direction to the regenerator, which quasi temporarily stores it. When flowing through in the other direction, the working medium then absorbs quantities of heat again from the regenerator. Consequently, a temperature gradient forms in the regenerator over its length and the regenerator reaches a temperature on the side adjoining the two volumes which largely corresponds to the temperatures prevailing in the volumes.

In a third step, the working medium in the second volume is largely isothermally expanded. It absorbs quantities of heat from the liquid that is disposed in the second volume and thereby keeps its temperature largely constant at the level that also largely corresponds to the temperature of the liquid in the second volume.

In a fourth step, the working medium is displaced from the second volume and flows back into the first volume via the same connection as in step two, where it largely assumes the temperature prevailing in the first volume as it flows through the connection and through the possible regenerator.

The circular process hereafter starts over again from the beginning with the first step. For this operation as a heat pump, mechanical energy must be expended in order to maintain this cyclic process and to supply corresponding quantities of heat to the one liquid and to remove it from the other liquid. This can be done, for example, by an electric drive.

This cyclic process can also be run in the opposite direction, so that the Stirling process can be used to implement a heat engine. In this case, the expansion of the working medium takes place in a first volume in contact with a first liquid and the compression of the working medium takes place in a second volume in contact with a second liquid, where the first liquid is warmer than the second one.

When the method of the present disclosure is implemented in the form of the Stirling process, it can be an alpha, beta or gamma Stirling process. Different variants of process control are also possible when it is implemented in the form of a different cyclic process such as the Ericsson process or the Clausius-Rankine process. Unlike the Stirling process, the Clausius-Rankine process also involves a phase transition in the working medium (change in the state of aggregation from gaseous to liquid and vice versa). In the case of the present disclosure, mixed forms of the process are also possible, for example a Stirling process in which part of the working medium evaporates or condenses during the compression and expansion.

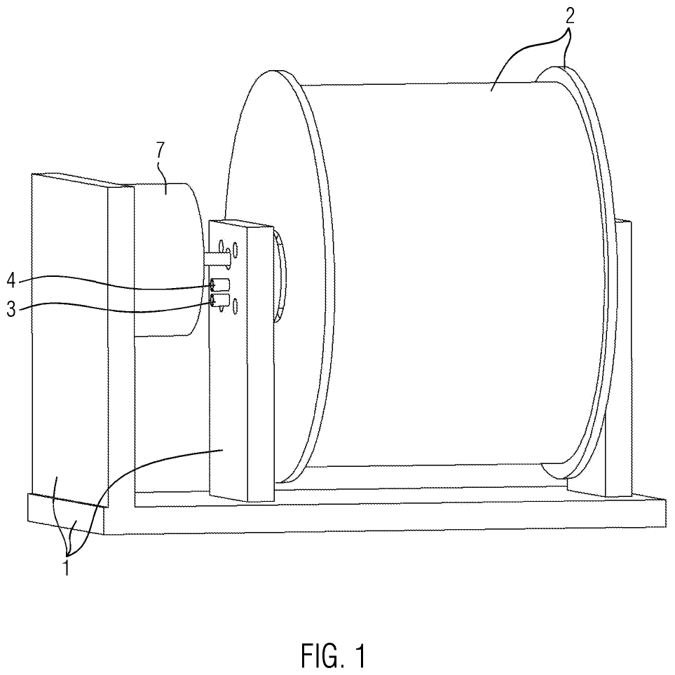

FIG. 1 shows a 3D view of a first embodiment of a thermodynamic converter which comprises devices for the compression, expansion, volume change, and/or displacement of a fluid containing a gas. A housing 2 is mounted on a frame 1 and is mounted to be freely rotatable by way of ball bearings (not shown). A first liquid can flow into or out of the interior of housing 2 through a first inlet line 3 and a first drain line 4. A motor 7, which is firmly connected to frame 1, can drive rotors that are referred to as the first and the second rotor and disposed in the interior of housing 2. Alternatively, motor 7 can also be operated as a generator for converting mechanical energy from the rotation of the rotors into electrical energy.

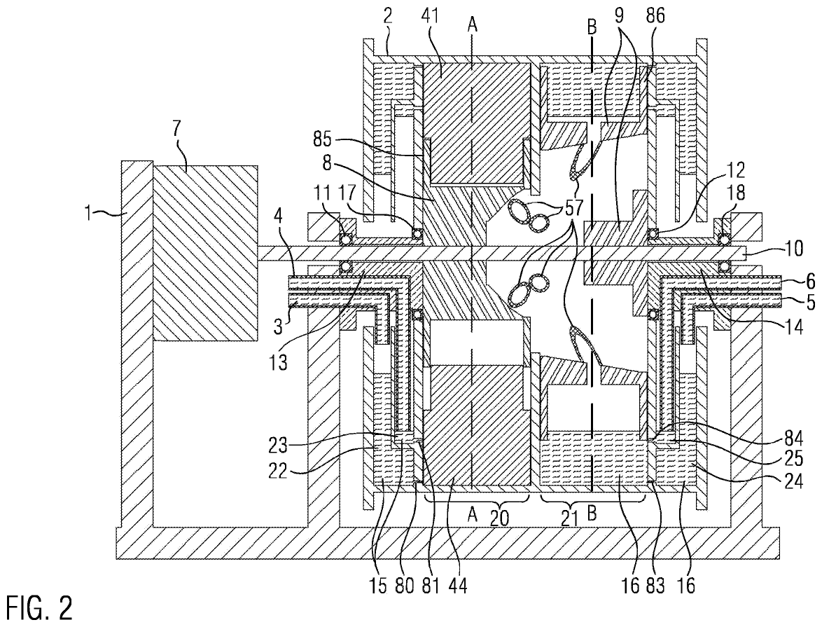

FIG. 2 shows a longitudinal sectional view of the device from FIG. 1. Motor 7 is mechanically fixedly connected by way of an axis 10 to first rotor 8 and second rotor 9. Axis 10 is mounted to be rotatable by way of two ball bearings 11, 12. Ball bearings 11, 12 are each held by a bearing block 13, 14 which is respectively fixedly connected to frame 1.

A second liquid 16 can flow into and out of the interior of housing 2 through a second inlet line 5 and a second drain line 6. Bearing blocks 13, 14 are also used to support first and second inlet and drain lines 3, 4, 5, 6 for first and second liquids 15, 16, respectively. Two ball bearings 17, 18 are also shown in the longitudinal section view, by way of which housing 2 is mounted to be rotatable, where the axis of rotation of rotors 8, 9 is parallel to the axis of rotation of housing 2, but not congruent. Rotors 8, 9 are mounted to be eccentric to the axis of rotation of housing 2. The interior of housing 2 is divided into six chambers 20, 21, 22, 23, 24, 25, each of which is rotationally symmetrical. First rotor 8, which is mounted to be eccentric to housing 2, is disposed in one inner chamber 20, which is also referred to as first main chamber 20, and second rotor 8, which is mounted to be eccentric to housing 2, is disposed in another inner chamber 21, which is also referred to as second main chamber 21. Rotors 8, 9 are not connected to housing 2 and can rotate within chambers 20, 21.

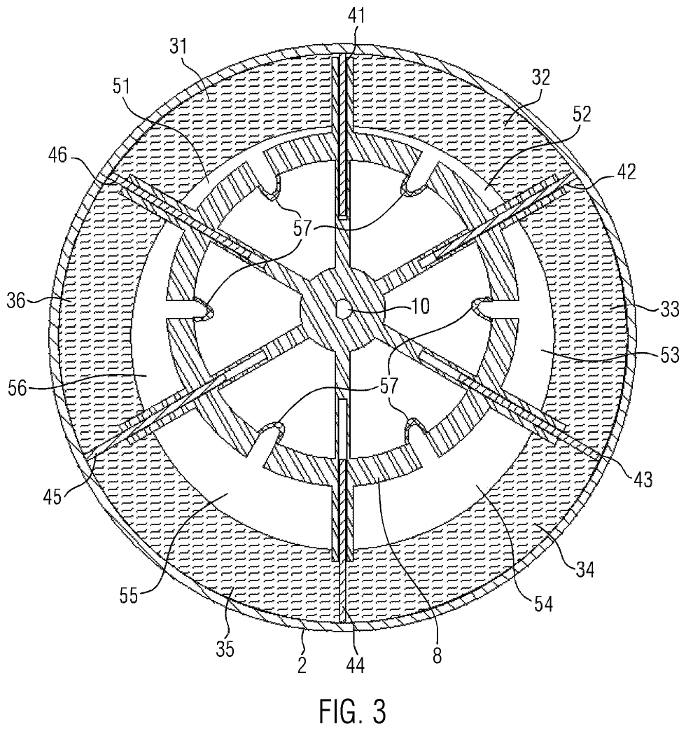

Movable limiting elements, two of which 41, 44 can be seen and whose function shall be explained in more detail in FIG. 3, are arranged in first main chamber 20.

Sections of connecting elements 57 that are permeable to gas are additionally to be seen in FIG. 2. Connecting elements 57 that are permeable to gas each connect a volume from first main chamber 20 to a different volume from second main chamber 21.

First liquid 15 can flow continuously into first main chamber 20 and thus in its volume (see FIG. 3) via first inlet line 3, chamber 22 and first openings 80, and can flow out again via second openings 81, chamber 23 and first drain line 4.

Second liquid 16 can flow into second main chamber 21 via second inlet line 5, chamber 24, and third openings 83 and can flow out again via fourth openings 84, chamber 25, and second drain line 6.

Rotors 8, 9 have a conical profile on the inside so that liquid that reaches the interior of rotors 8, 9 can flow out through narrow first and second gaps 85, 86, respectively, disposed on the outside.

FIG. 3 shows a cross section (section A-A) through first main chamber 20 within which first rotor 8 is disposed.

First rotor 8 divides first main chamber 20 into six volumes 31, 32, 33, 34, 35, 36, each of which is defined by a part of housing 2 as well as by limiting elements 41, 42, 43, 44, 45, 46 that are movable relative to first rotor 8 and together form so-called volume limiting elements.

A volume can contain the working medium (a gas, a gas mixture or a mixture of gas(es) with a liquid mist) as well as a liquid and can be limited by the volume limiting elements except for gaps or openings for the supply or removal of the working medium or the liquid. These gaps or openings can be dimensioned such or be connected to other volumes such that, for example, only a very small pressure loss is caused thereby during a compression or expansion process and that the liquid flows out of the volume through these gaps or openings or flows into the volume (<10% of the liquid quantity in the volume). The direct contact of the working medium with the liquid ensures that the working medium is thermally coupled to the liquid very effectively.

Disposed within each volume 31-36 is a respective partial volume 51, 52, 53, 54, 55, 56, which is filled with a working medium (e.g. air), as well as part of first liquid 15. First liquid 15 is respectively accelerated outwardly by the centrifugal forces. Limiting elements 41-46 are guided by slots in first rotor 8 and are freely movable radially therein. As soon as first rotor 8 rotates at a sufficient speed, limiting elements 41-46 are pressed radially outwardly by the centrifugal force until they reach the outer wall of housing 2. In this way they prevent first liquid 15 from flowing from one volume (e.g. 31) into an adjacent volume (e.g. 32).

Alternatively, the use of springs or the like is also conceivable for pressing limiting elements 41-46 against housing 2 from the inside.

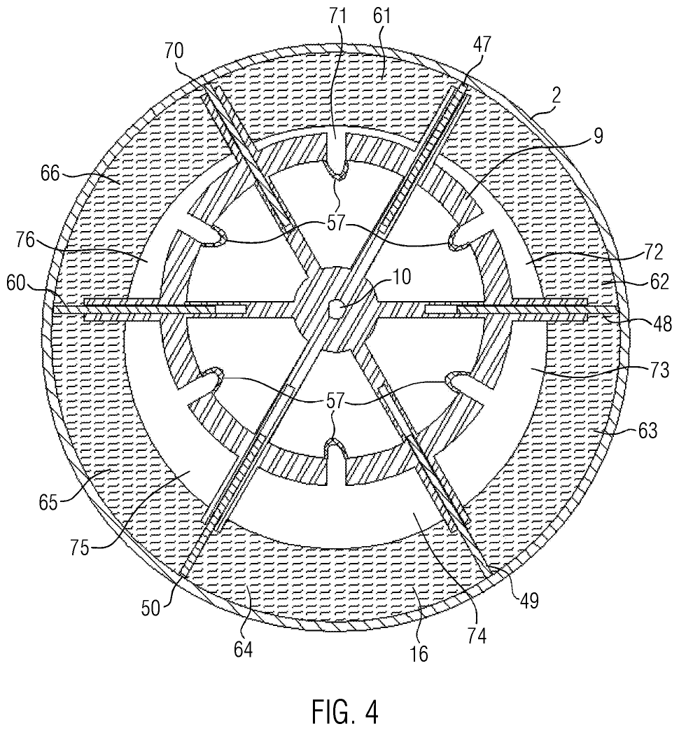

FIG. 4 shows a cross section (section B-B) through second main chamber 21 within which second rotor 9 is disposed.

Second rotor 9 in second main chamber 21 is configured to be identical to first rotor 8. Compared to first rotor 8, however, second rotor 9 is attached on axis 10 rotated by a certain angle.

Second rotor 8 divides second main chamber 20 into six volumes 61, 62, 63, 64, 65, 66, each of which is defined by a part of housing 2 as well as by second rotor 9 and limiting elements 47, 48, 49, 50, 60, 70 that are movable relative to second rotor 9 and together form so-called volume limiting elements.

Disposed within each volume 61-66 is a partial volume 71, 72, 73, 74, 75, 76, which is filled with a working medium (e.g. air), as well as part of second liquid 16. Second liquid 16 is respectively accelerated outwardly by the centrifugal forces. Limiting elements 47, 48, 49, 50, 60, 70 are guided by slots in second rotor 9 and are freely movable radially therein. As soon as second rotor 9 rotates at a sufficient speed, limiting elements 47, 48, 49, 50, 60, 70 are pressed radially outwardly by the centrifugal force until they reach the outer wall of housing 2. In this way they prevent second liquid 16 from flowing from one volume (e.g. 61) into an adjacent volume (e.g. 62).

Alternatively, the use of springs or the like is also conceivable for pressing limiting elements 47, 48, 49, 50, 60, 70 against housing 2 from the inside.

One respective volume (e.g. 31) from first main chamber 20 is connected to one respective volume (e.g. 63) from second main chamber 21 by way of one of connecting elements 57 that are permeable to gas, so that pressure equalization takes place continuously by the working medium from the partial volume (e.g. 51) of first main chamber 20 into the partial volume (e.g. 73) of second main chamber 21. These connecting elements 57 can be filled with a regenerator material, such as steel wool or other material (preferably metal) that is permeable to gas and has a large surface area to enable it to very quickly exchange quantities of heat with the fluid flowing past.

The implementation of the Stirling process can be explained on the basis of FIG. 3 and FIG. 4.

The four steps of the cyclic process shall now be explained hereafter with reference to two volumes 31 and 63 of first main chamber 20 and second main chamber 21, respectively. In other volumes (32 with 64, 33 with 65, 34 with 66, 35 with 61, 36 with 62) the cyclic process runs analogously, but phase-shifted compared to volumes 31 and 63. It is therefore a six-fold process alpha Stirling process.

In the starting position shown in FIGS. 3 and 4, the working medium of volumes 31 and 63 is disposed to the largest part in partial volume 73; as can be seen in FIG. 3, partial volume 51 is small compared to partial volume 73. If two rotors 8, 9 now continue to rotate onward clockwise (e.g. by 60° to the position of volumes 32 and 64 illustrated), then the sum of the partial volumes 51 and 73 increases. The working medium is therefore expanded. In doing so, it hardly cools down, since it can absorb heat energy primarily from second liquid 16, to which most of the working medium adjoins—the expansion therefore takes place largely isothermally. With a further rotation of rotors 8, 9, partial volume 73 is reduced and partial volume 51 is increased. The working medium therefore flows from partial volume 73 into partial volume 51 through connecting element 57 and through the regenerator disposed therein. It largely assumes the temperature of first liquid 15 to which the side of connecting element 57 and of regenerator facing partial volume 51 was previously heated. Partial volume 51 is now approximately at the position of partial volume 54 illustrated in FIG. 3 and partial volume 73 at the position of partial volume 76 illustrated in FIG. 4 and the largest part of the working medium is disposed in partial volume 51. With a further clockwise rotation of rotors 8, 9, the sum of partial volumes 51 and 73 is reduced and the working medium is compressed—again largely isothermally. In the process, quantities of heat are released primarily to first liquid 15 since the majority of the working medium is disposed in volume 31 and is there thermally coupled to first liquid 15. With a further rotation of rotors 8, 9 to the starting position illustrated in FIG. 3 and FIG. 4, partial volume 51 is reduced and partial volume 73 is increased so that the working medium again flows through connecting element 57 and the regenerator into partial volume 73 and, in doing so, largely assumes the temperature of second liquid 16.

In this process, therefore, first liquid 15 is heated and second liquid 16 is cooled down. Mechanical energy must be expended for the compression by way of the rotation of rotors 8, 9, as a result of which of the rotors are braked, and rotors 8, 9 are driven and thus accelerated by the expansion.

If second liquid 16 is warmer than first liquid 15, then the rotors are accelerated more strongly by the expansion of the working medium than they are slowed down by the compression of the working medium. If this energy difference is greater than the mechanical friction in the system, including the flow losses of the liquids, then motor 7 can be driven thereby and generate electrical energy.

If first liquid 15 is warmer than second liquid 16, then motor 7 must expend mechanical energy to drive rotors 8, 9—but this can further heat first liquid 15 and further cool second liquid 16, so that the method operates like a heat pump. First liquid 15 can flow continuously into first main chamber 20 and thus in into volumes 31-36 via first inlet line 3, chamber 22 and first openings 80, and can flow out again via first openings 81, chamber 23, and first drain line 4. In the process, liquid rings are formed in chambers 22 and 23. Likewise, second liquid 16 can flow into second main chamber 21 via second inlet line 5, chamber 24, and openings 83 and can flow out again via openings 84, chamber 25, and second drain line 6, where liquid rings there form in chambers 24 and 25. In this way, first and second liquids 15, 16 can be coupled to external heat reservoirs, or useful heat and useful cold can be removed from the system, or driving heat and driving cold can be entered into the system, respectively. The length of first and second drain lines 4, 6 there also regulates the height of the liquid rings in chambers 23 and 25 and thereby also the height of the rotating liquid quantities in volumes 31-36 of first main chamber 20 and volumes 61-66 of second main chamber 21. Since rotors 8, 9 have a conical profile on the inside, liquid that reaches the interior of rotors 8, 9 can flow out through narrow gaps 85, 86, respectively disposed on the outside. Housing 2 is mounted to be rotatable by way of ball bearings 17, 18 so that it can co-rotate during operation. In this way, the motion of housing 2 relative to rotors 8, 9, to first and second liquids 15, 16, and to movable limiting elements 41-46, 47, 48, 49, 50, 60, 70 is minimized and friction losses are minimized accordingly.

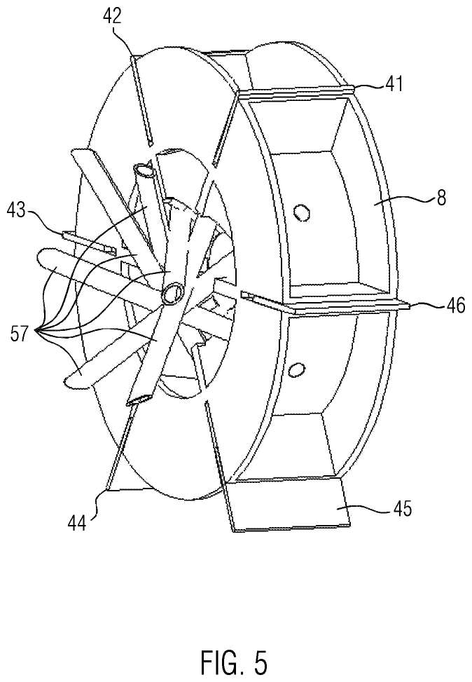

FIG. 5 shows a three-dimensional oblique view of first rotor 8 together with connecting elements 57, which connect partial volumes 51-56 of first main chamber 20 to respective partial volumes 71, 72, 73, 74, 75, 76 of the second main chamber and can contain a regenerator material. Movable limiting elements 41-46 of first rotor 8 can also be seen. Connecting elements 57 can be provided such that the following assignment of the partial volumes is accomplished 51 to 73, 52 to 74, 53 to 75, 54 to 76, 55 to 71, 56 to 72.

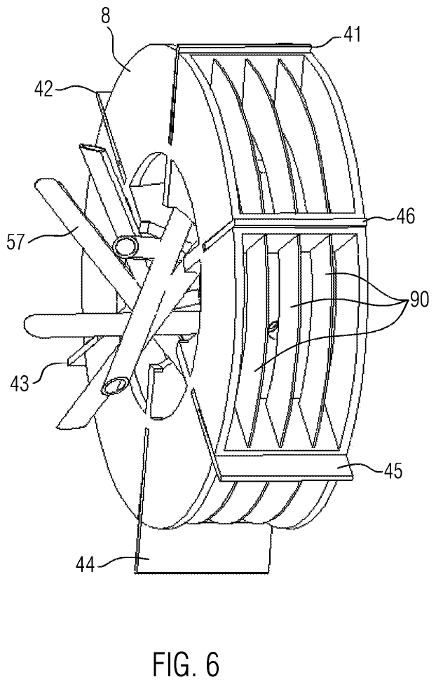

FIG. 6 shows an alternative embodiment of first rotor 8 which comprises the same elements as in FIG. 5 and in which additional heat exchange elements 90 are provided which, during the rotation of first rotor 8, immerse to different depths into first liquid 15, i.e. regions thereof exist which are at certain times disposed within first liquid 15 and at other times outside of first liquid 15 and therefore within the working medium in one of partial volumes 51-56. While heat exchange elements 90 are immersed in first liquid 15, they are thermally coupled thereto and can largely assume the temperature of first liquid 15. While heat exchange elements 90 do not immerse into first liquid 15, they are thermally coupled to the working medium and can largely transfer their temperature thereto. The additional heat exchanger elements 90 contribute to improving or accelerating the exchange of quantities of heat between the working medium and first liquid 15.

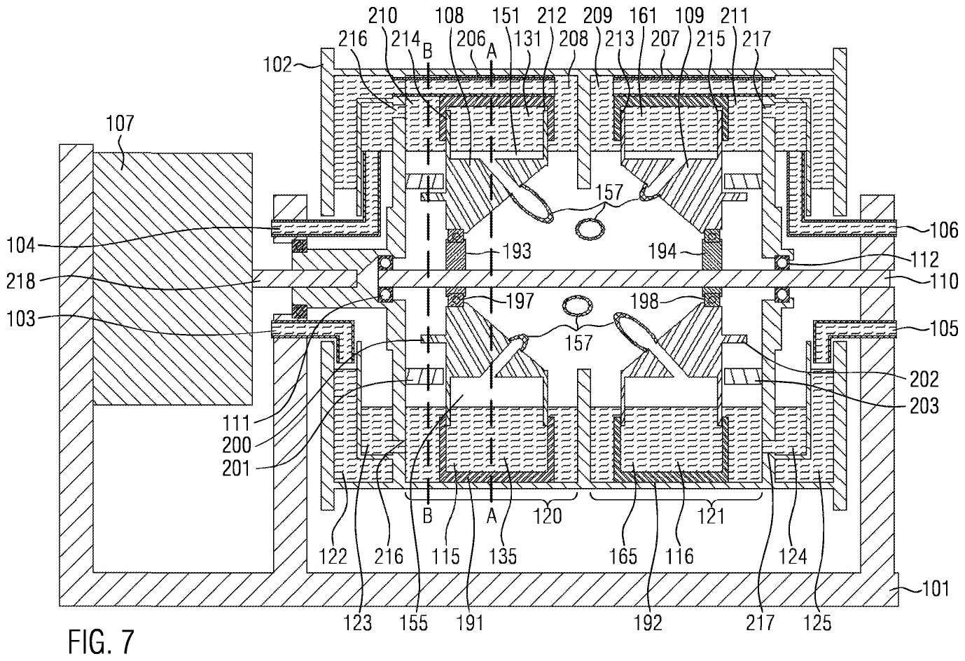

FIG. 7 shows a longitudinal sectional view of a second embodiment of a thermodynamic converter which comprises devices for the compression, expansion, volume change and/or displacement of a fluid containing a gas.

Mounted on a frame 101 is a housing 102 that is mounted to be freely rotatable by way of ball bearings 111, 112 and to be concentrical to axis 110. A motor 107, which is firmly connected to frame 101, can drive housing 102 and rotors 108, 109 that are disposed in the interior of housing 102 and are referred to as first and the second rotor 108, 109. Alternatively, motor 107 can also be operated as a generator for converting mechanical energy from the rotation of rotors 108, 109 into electrical energy.

Axis 110 is connected to frame 101 in a fixed and non-rotatable manner. Two eccentrics 193, 194 are fixedly mounted on this axis 110 and ensure that ball bearings 197, 198 are in an eccentric position relative to axis 110. Two rotors 108, 109 are mounted to be rotatable by way of these two ball bearings 197, 198 so that they can perform a rotational motion that is eccentric to axis 110 and thus also eccentric to housing 102.

Rotors 108, 109 are mechanically coupled to housing 102 by way of gears 200, 202, which are firmly connected to rotors 108, 109, and by way of internal gears 201, 203, which are firmly connected to housing 102, in such a way that the rotational speeds of rotors 108, 109 have a fixed ratio to the rotational speed of housing 102.

Axis of rotation 218 of motor 107 is fixedly connected to housing 102 and can cause it to rotate or absorb rotational energy therefrom in order to convert it into electrical energy. The rotational motion of the axis of rotation 218 of motor 107 is also indirectly coupled to the rotational motion of rotors 108, 109 by way of gears 200, 202 and internal gears 201, 203.

A first liquid 115 can flow into and out of the interior of housing 102 through a first inlet line 103 and a first drain line 104. A second liquid 116 can flow into and out of the interior of housing 102 through a second inlet line 105 and a second drain line 106.

The interior of housing 102 is divided into six chambers 120, 121, 122, 123, 124, 125, each of which is rotationally symmetrical. First rotor 108, which is mounted to be eccentric to housing 102, is disposed in an inner chamber 120, which is also referred to as first main chamber 120, and second rotor 109, which is mounted to be eccentric to housing 2, is disposed in other inner chamber 121, which is also referred to as second main chamber 121. Rotors 108, 109 are not connected to housing 102 and can rotate within chambers 120, 121.

Sections of connecting elements 157 that are permeable to gas can additionally be seen in FIG. 7. Connecting elements 157 that are permeable to gas each connect a volume from first main chamber 120 to a different volume from second main chamber 121. Two volumes 131, 135 of the total of six volumes and two partial volumes 151, 155 of first main chamber 120 and two volumes 161, 165 of second main chamber 121 are shown.

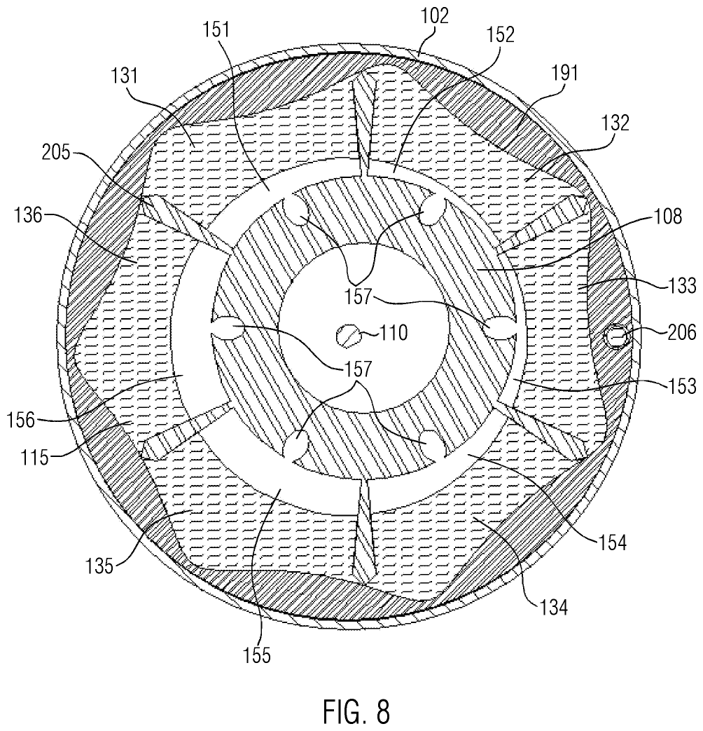

In this second embodiment, first liquid 115 flows through the device through inlet line 104 into chamber 122 and from there via a first line 206 into a chamber 208 of first main chamber 120. From there it passes through a gap 212 with a certain flow resistance into the volumes of first main chamber 120 (see FIG. 8) where it is heated or cooled during operation. First liquid 115 can leave the volume of first main chamber 120 again via a gap 214 and reaches chamber 210, then through an opening 216 into chamber 123 in which it forms a liquid ring. From there it can leave the device again via first drain line 104, where first drain line 104 with its length in the radial direction defines the height up to which the water ring forms in chambers 123 and 210 to which the filling levels of the first liquid 115 in the volumes of first main chamber 120 adjust.

In the same way, second liquid 116 flows through the device via second inlet line 105, chamber 124, a second line 207, a chamber 209 of second main chamber 121. From there, second liquid 116 flows through a gap 213 with a certain flow resistance into the volumes of second main chamber 121. Second liquid 216 can leave the volumes of second main chamber 121 again via a gap 215 and enters chamber 211, then through openings 217 into chamber 125 and leaves the device through second drain line 106.

FIG. 8 shows a first cross section (section A-A) through first main chamber 120, Volumes 131, 132, 133, 134, 135, 136, in which partial volumes 151, 152, 153, 154, 155, 156 containing working medium are disposed are formed by first rotor 108 and outer limiting element 191 as volume limiting elements. Outer limiting element 191 is fixedly connected to housing 102 and is disposed together with first rotor 108 in first main chamber 120. The cross section of first conduit 206 can be seen.

Outer limiting element 191 is shaped such that the elements protruding outwardly in a star shape from first rotor 108 together with limiting element 191 always form only a very fine gap 205 through which only very small quantities of first liquid 115 can flow per unit of time and during operation only a very small liquid exchange or pressure equalization between adjacent volumes (e.g. 131 and 132) can then take place.

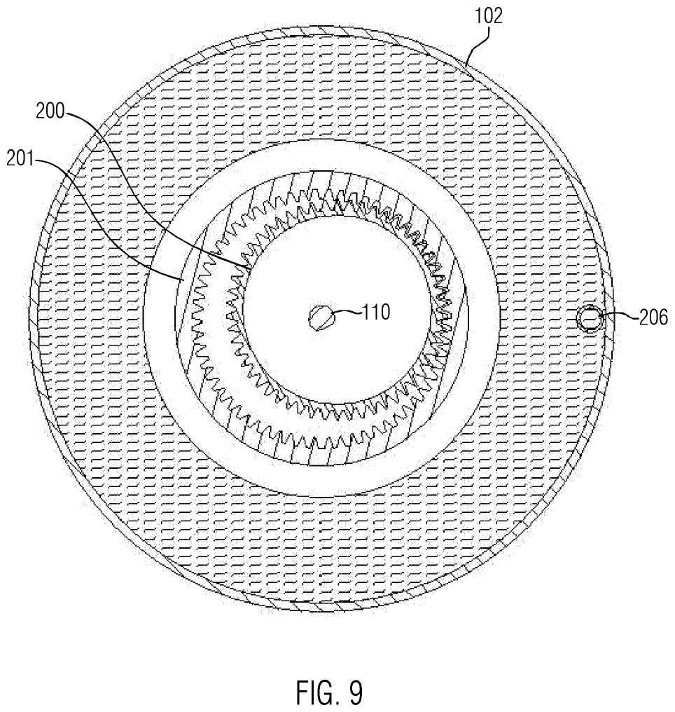

FIG. 9 shows a second cross section (section B-B) through first main chamber 120. It can be seen how gear 200, which is fixedly connected to first rotor 108, and internal gear 201, which is fixedly connected to housing 102, intermesh, whereby first rotor 108 is mechanically coupled to housing 102 such that the rotational speed of first rotor 108 has a fixed ratio to the rotational speed of housing 102.

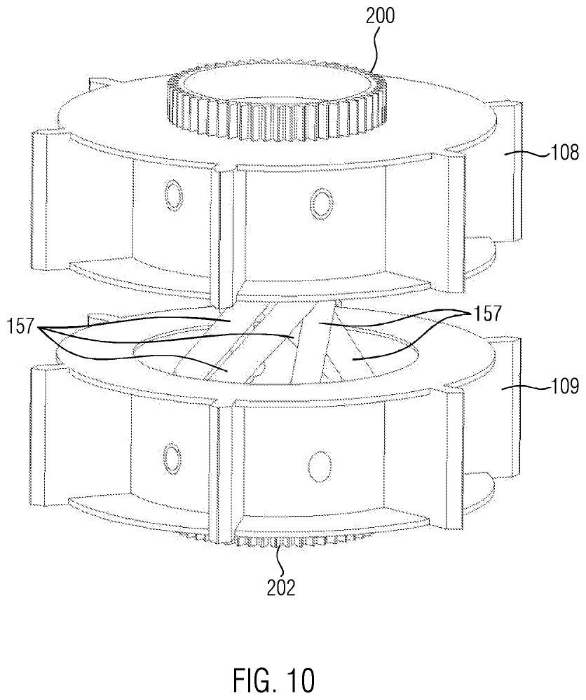

FIG. 10 shows a three-dimensional view of rotors 108, 109 together with connecting elements 157 that are permeable to gas and via which the working medium can flow from partial volumes 151, 152, 153, 154, 155, 156 of first rotor 108 into a respective one of the partial volumes of second rotor 109 and vice versa. The working medium can change its temperature via the wall of connecting elements 157 or additionally via a regenerator disposed in connecting element 157. Gear 200, which is firmly connected to first rotor 108, and gear 202, which is firmly connected to second rotor 109, are also shown. Rotors 108, 109 each have circular volume limiting elements on both sides perpendicular to their axis of rotation which prevent the working medium from escaping laterally.

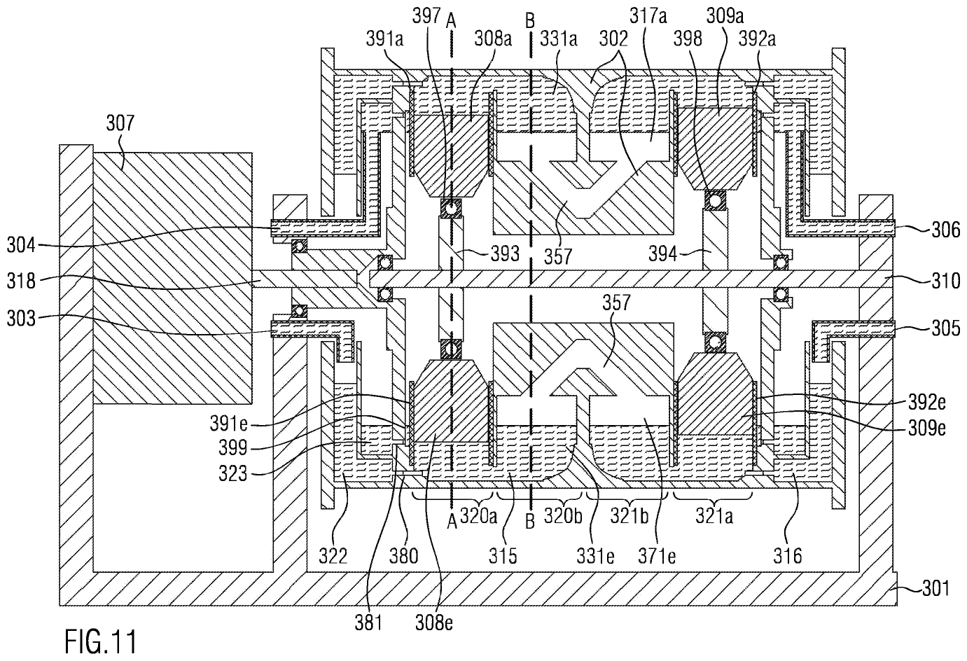

A third embodiment of a device for the compression, expansion, volume change, and/or displacement of a fluid containing a gas is shown in FIGS. 11, 12 and 13.

FIG. 11 shows a longitudinal sectional view through a third embodiment of a thermodynamic converter which comprises devices for the compression, expansion, volume change and/or displacement of a fluid containing a gas.

The eight volumes filled with working medium and first liquid 315 (two of them, namely 331a, 331e, can be seen in the illustration) are disposed there in first main chamber 320a and second main chamber 320b of housing 302. The eight volumes filled with working medium and second liquid 316 (two of them, namely 371a, 371e, can be seen in the illustration) are disposed there in third main chamber 321a and fourth main chamber 321b of housing 302.

Eccentrics 393, 394 are fixedly connected to stationary axis 310 which is fixedly connected to the frame 301.

Fastened to eccentric 393 is ball bearing 397 which limits the position of eight pistons (two of which, namely 308a, 308e, can be seen in the illustration) in first main chamber 320a in that it prevents them by contact from moving further into the interior of the device. Fastened to eccentric 394 is ball bearing 398 which limits the position of six pistons (two of which, namely 309a, 309e, can be seen in the illustration) in third main chamber 321a in that it prevents them by contact from moving further into the interior of the device.

Since all of sixteen pistons (308a, 308e, 309a, 309e) have a lower density than first or second liquid 315, 316, respectively, they “float” on respective liquid 315, 316 so that they typically also always contact respective ball bearings 397, 398. Axis of rotation 318 of motor 307 is fixedly connected to housing 302 that is mounted to be rotatable and can rotate or brake the latter.

First main chamber 320a also comprises eight cylinders (two of which, namely 391a, 391e, can be seen in the illustration). Third main chamber 321a also comprises eight cylinders (two of which, namely 392a, 392e, can be seen in the illustration).

First liquid 315 can be discharged through a first supply line 303 into first and second main chamber 320a, 320b and through a first drain line 304 therefrom.

Second liquid 316 can be discharged through a second supply line 305 into third and fourth main chamber 321a, 321b and through a second drain line 306 therefrom.

Eight volumes 331a, 331e of second main chamber 320b can each be connected to six volumes 371a, 371e of fourth main chamber 321b by way of connecting elements 357 that are permeable to gas.

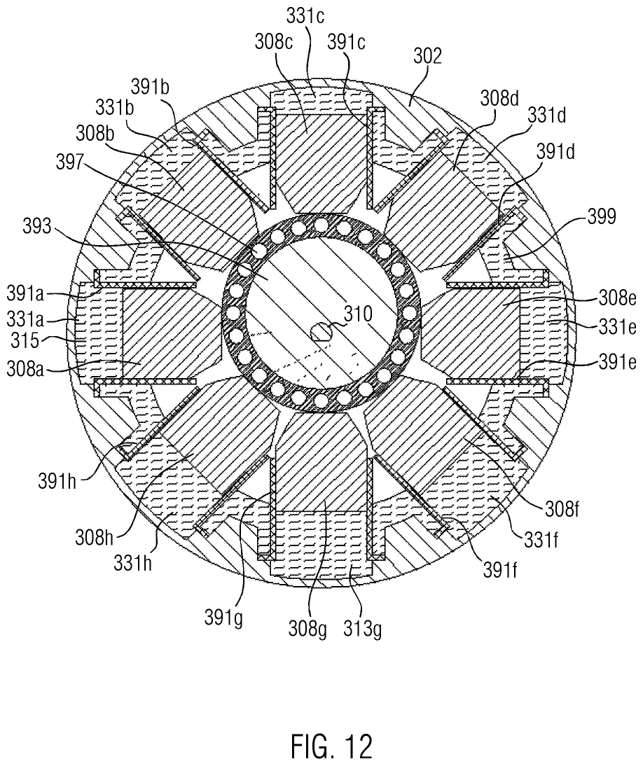

FIG. 12 shows a cross section (section A-A) through first main chamber 320a which comprises volumes 331a, 331b, 331c, 331d, 331e, 331f, 331g, 331h with the working medium and first liquid 315.

First eccentric 393, on which ball bearing 397 is attached, is firmly connected to axis 310. Ball bearing 397 limits the position of pistons 308a, 308b, 308c, 308d, 308e, 308f, 308g, 308h in that it prevents them by contact from moving into the interior of the of the machine.

When housing 302 rotates, cylinders 391a, 391b, 391c, 391d, 391e, 391f, 391g, 391h also rotate, since they are firmly connected to housing 302. In cylinders 391a-391h, pistons 308a-308h can move freely in the radial direction and their position is respectively defined by ball bearing 397 attached on eccentric 393. During a complete rotation of housing 302 by 360°, pistons 308a-308h consequently perform not only their rotational motion about axis of rotation 310 of housing 302 but also a respective period of an oscillating motion in the radial direction. Together with housing 302 and cylinders 391a-391h, pistons 308a-308h form the volume limiting elements of volumes 331a-331h which each contain the working medium and first liquid 315, respectively.

If the piston (e.g. 308a) in a volume (e.g. 331a) is pressed radially outwardly by the rotation of housing 302, it displaces the liquid (e.g. 315) in the volume (e.g. 331a) in this manner in the direction of the main chamber (e.g. 320b) disposed further inwardly so that it displaces the working medium adjoining it from the volume (e.g. 331a) into the volume (e.g. 371a) that is connected to it by way of connecting element 357 and/or compresses the working medium. Connecting element 357 can contain a regenerator material. If two eccentrics 393, 394 cause a suitable phase shift between the two pistons (e.g. 308a and 309a) due to their position, which define two volumes which are each connected to one another by way of a connecting element 357, then this embodiment can again be used to realize an alpha Stirling process in the application as a heat pump or as a heat engine.

First liquid 315 passes through the machine through first inlet line 303, through chamber 322, through openings 380, through volumes 331a-331h, driven by the overpressure in volumes 331a-331h through the gaps between pistons 308a-308h and cylinders 391a-391h, through interior 399 of main chamber 320a, through openings 381, through chamber 323, and through first drain line 304. Second liquid 316 flows through the device analogously.

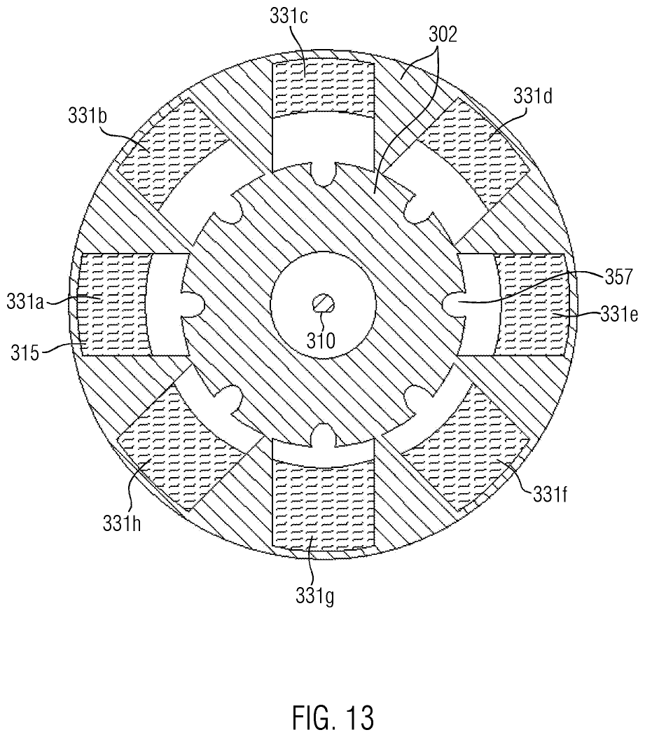

FIG. 13 shows a cross section (section B-B) through second main chamber 320b which comprises volumes 331a-331h with the working medium and first liquid 315. In addition, parts of housing 302 are shown in which volumes 331a-331h are arranged.

Sections of connecting elements 357 that are permeable to gas, which each connect a volume 331a-331h from respective first and second main chamber 320a, 320b to a volume from third and fourth main chamber 321a, 321b, can also be seen in FIG. 13. For example, volumes 331a and 371a can be connected by a connecting element 357.

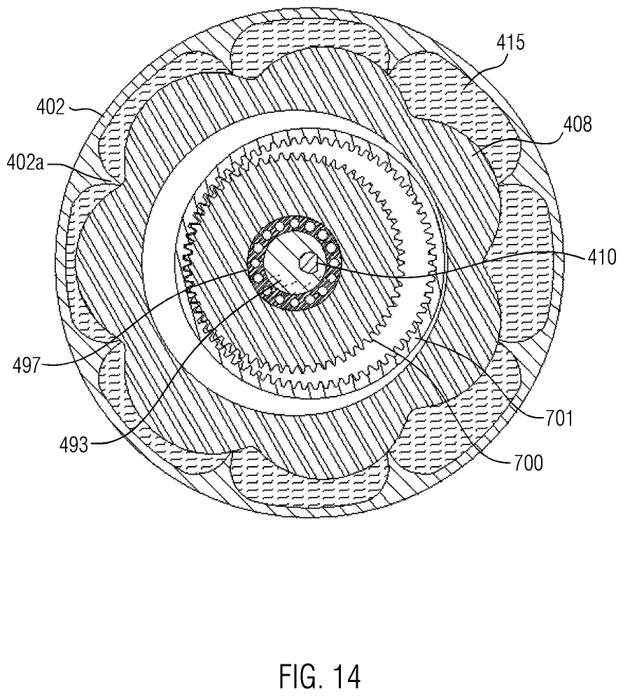

As shown in FIG. 14, the elements provided in FIG. 11 in an alternative embodiment in first main chamber 320a and third main chamber 321a, which have the function of periodically displacing in and out first and second liquid 315, 316 in the direction of the second main chamber 320b and fourth main chamber 321b, respectively, are replaced by a rotary piston 408. Rotary piston 408 performs a rotation about an axis of rotation passing through the center of ball bearing 497 by which it is mounted to be rotatable. The axis of rotation of rotary piston 408 is eccentric to the axis of rotation of housing 402 which corresponds to the position of stationary axis 410. The position of the two axes of rotation relative to one another is defined by eccentric 493 on which rotary piston 408 is mounted to be rotatable by way of ball bearing 497. Gear 700 integrated into rotary piston 408 as well as internal gear 701, which is firmly connected to housing 402, ensure, analogously to the second embodiment from FIG. 7, that the rotational speeds of these two rotations of housing 402 and rotary piston 408 have a constant ratio to each other. It can thus be ensured that rotary piston 408 causes the periodic displacement of first liquid 415 described above, where the gaps between sealing elements 402a fixedly connected to housing 402 and rotary piston 408 always remain very small. Additional sealing strips, which are attached to be movable at the tips of sealing elements 402a and are pressed against rotary piston 408 by way of springs or similar force-generating elements, can further reduce the gap width between sealing elements 402a and rotary piston 408 and improve the sealing effect accordingly.

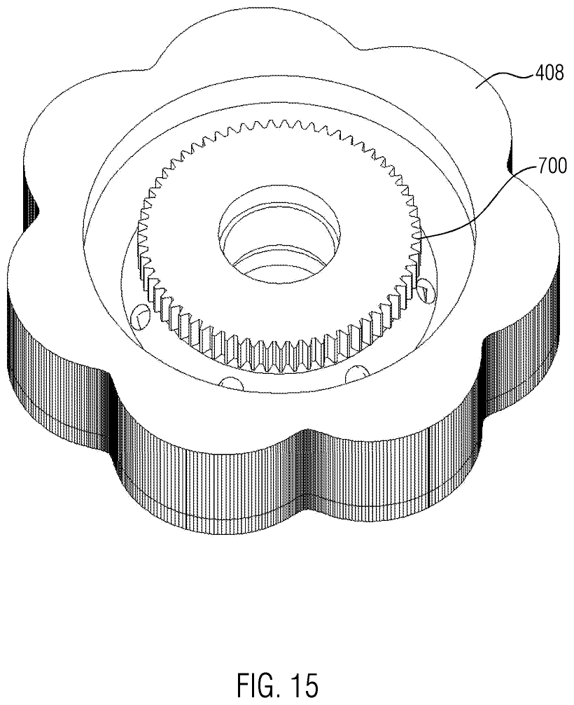

FIG. 15 shows rotary piston 408 with internal gear 700 in a three-dimensional view.

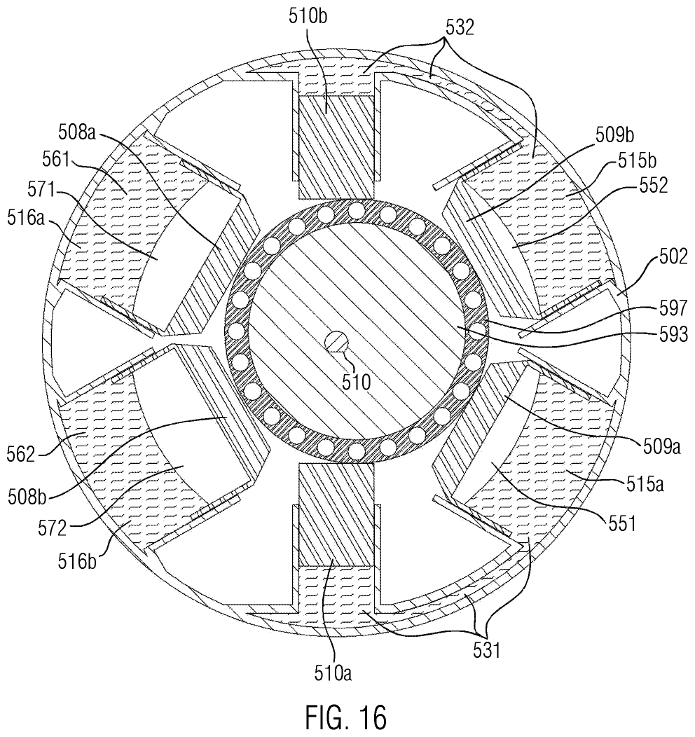

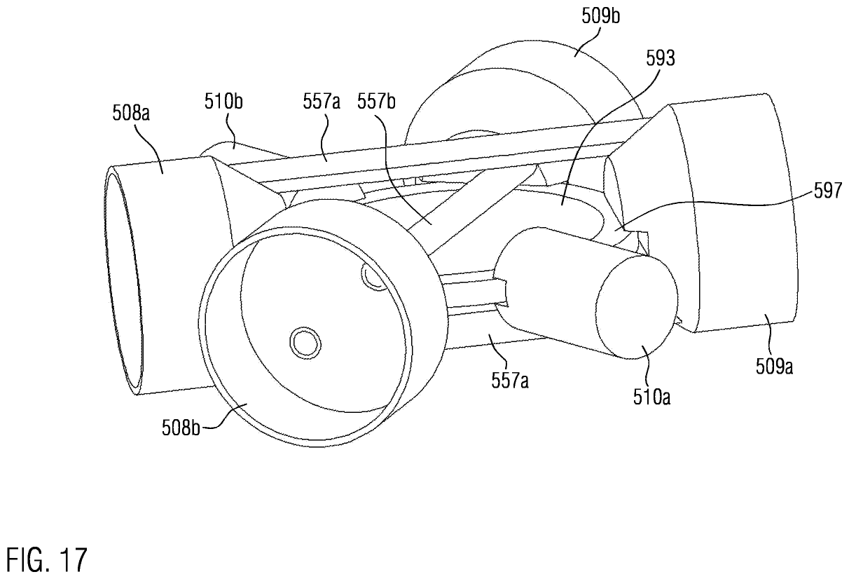

FIGS. 16 and 17 shows a view of a further embodiment of a thermodynamic converter which comprises devices for the compression, expansion, volume change, and/or displacement of a fluid containing a gas. Unlike the embodiments shown in FIGS. 1 to 15, this further embodiment implements a Stirling process in the variant as a beta Stirling process.

The embodiment shown in the cross-section of FIG. 16 comprises an axis 510 which is fixedly connected to an outer stationary frame and is non-rotatable. An eccentric 593 is firmly connected to axis 510 so that it is likewise stationary. A ball bearing 597 sits on eccentric 593 and limits radially inwardly the motion of hollow pistons 508a, 508b, 509a, 509b and of compressor pistons 510a, 510b. Hollow pistons 508a, 508b, 509a, 509b have the function of a “displacement piston” and compressor pistons 510a, 510b have the function of a “working piston”, which are the typical terms for beta Stirling engines.

In this further embodiment, the axis of rotation of a motor is firmly connected to housing 502 that is mounted to be rotatable and can accelerate or decelerate the latter's rotational motion. The axis of rotation of housing 502 corresponds to the position of stationary axis 510. Compressor pistons 510a, 510b have a lower density than liquids 515a, 515b, 516a, 516b contained in housing 502 which are pressed radially outwardly by the centrifugal force when housing 502 is rotated. Compressor pistons 510a, 510b therefore “float” on liquid 515a, 515b and are pushed radially inwardly thereby until this motion is limited by ball bearing 597 mounted on eccentric 593. Radially oppositely disposed hollow pistons 508a, 508b, 509a, 509b are connected to one another by way of connecting elements that are permeable to gas (see FIG. 17) so that each hollow piston that is pressed radially outwardly by ball bearing 597 thereby pulls the oppositely disposed hollow piston inwardly.

Volumes 531, 532, 561, 562 are defined by the following volume limiting elements: housing 502, which forms six cylinders in the radial direction inwardly, and hollow pistons 508a, 508b, 509a, 509b which are arranged to be movable in the cylinders, and displacement pistons 510a, 510b. Disposed within these volumes 531, 532, 561, 562 are also partial volumes 551, 571 filled with the working medium which are defined by liquids 515a, 515b, 516a, 516b, hollow pistons 508a, 508b, 509a, 509b, compressor pistons 510a, 510b, and the connecting elements.

Partial volumes 551, 571 filled with the working medium are connected to one another by two connecting elements that are permeable to gas, where the connecting elements can contain a regenerator material. Due to the motion of hollow pistons 508a, 509a caused by the rotation of the housing, partial volumes 551, 571 are alternately reduced and enlarged, where a partial volume (e.g. 551) is particularly small if the partial volume disposed radially opposite thereto (e.g. 571) is particularly large and vice versa. Depending on the direction of rotation of housing 502, partial volume 551 forms the expansion space of a beta Stirling process and partial volume 571 the compression space (or vice versa). The working medium is moved back and forth alternately between two partial volumes 551, 571, where it flows through the connecting elements. Within partial volumes 551, 571, the working medium is respectively thermally coupled to one of liquids 515a, 516b and can absorb quantities of heat therefrom or release them thereto. While flowing through the connecting elements, it can be heated or cooled such that when it enters partial volumes 551, 571, it has already largely assumed their temperature.

The displacement piston 510a likewise performs a periodic motion in the radial direction. In doing so, it displaces liquid 515a such that partial volume 551 is reduced or enlarged. This changes the pressure in partial volumes 551, 571 which causes the compression and expansion of the working gas and consequently its change in temperature. However, this change in temperature occurs only to a small extent, since partial volumes 551, 571 are thermally coupled to liquids 515a or 516a, respectively, and can dissipate quantities of heat thereto or absorb them thereform and thereby continuously adjust their temperature to that of liquids 515a or 516a, respectively. By positioning displacement piston 510a, the phase shift of its radial sinusoidal motion can be defined compared to the radial sinusoidal motion of reciprocating pistons 508a and 508b. In the case shown, the phase shift between displacement piston 510a and hollow piston 509a is 60°. In a further preferred embodiment, this phase shift is 90°, where displacement pistons 510a, 510b do not have to lie in the same plane perpendicular to the axis (510) like reciprocating pistons 508a, 508b, 509a, 509b. Partial volumes 552, 572 form a beta Stirling process in an analogous manner, where the change in pressure in this case is caused by the radial motion of displacement piston 510b.

FIG. 17 shows a three-dimensional view of reciprocating pistons 508a, 508b, 509a, 509b, displacement pistons 510a, 510b, connecting elements 557a, 557b, eccentric 593, and ball bearing 597.

As a result of this arrangement, for example, radially oppositely disposed hollow pistons 508a, 509a in FIG. 16 can be connected to one another by way of connecting element 557b that is permeable to gas, and radially oppositely disposed hollow pistons 508b, 509b can be connected to one another by way of connecting element 557a that is permeable to gas. Therefore, for example, partial volumes 551, 571 filled with the working medium are connected to one another by connecting element 557b that is permeable to gas.

Further embodiments in which the expansion and compression of a working medium are caused by a rotating liquid quantity made to oscillate by inertial forces are possible. For example, a liquid quantity can be made to oscillate by varying centrifugal forces by way of a periodically fluctuating rotational speed. It is also possible to superimpose a further periodic motion on the rotational speed, e.g. a rotation about another axis, causing a rotating liquid quantity to perform an oscillating motion.

A further embodiment is given in that the stationary axis (e.g. 110) in the embodiment shown in FIGS. 7 to 10 is replaced by an axis rotating at a certain speed. It can be achieved in this manner that the rotation of the housing (e.g. 102) is higher in comparison to the frequency of the realized Stirling process than in the embodiments shown in FIGS. 7 to 10. In this way, the centrifugal force that presses the liquid quantities from the inside against the outer wall of the housing (e.g. 102) can be further increased without increasing the frequency of the Stirling process at the same time. This is analogously possible also in the embodiment from FIGS. 11 to 13, from the embodiment from FIGS. 14 and 15, or in the embodiment from FIGS. 16 and 17.

In addition to the embodiments of a Stirling process presently mentioned, which can be operated as a heat pump or a heat engine, an embodiment is also to mechanically couple one of these embodiments operating as a heat engine to another embodiment operating as a heat pump. In this way, useful heat and/or useful cold can be generated from the use of a temperature difference between two different heat reservoirs (e.g. ambient heat or waste heat from an industrial process and a suitable heat sink). This may be beneficial since the effective coupling of the working medium to a liquid as a heat transfer medium also allows for the use of small temperature differences in such an application and therefore also makes use of waste heat or ambient heat that has only small temperature differences to a present heat sink.

It is to be understood that the above description is intended to be illustrative, and not restrictive Many other embodiments will be apparent upon reading and understanding the above description. Although embodiments of the present disclosure have been described with reference to specific example embodiments, it will be recognized that the present disclosure is not limited to the embodiments described, but can be practiced with modification and alteration within the spirit and scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

1. A device comprising:
at least one volume that comprises a liquid quantity of a liquid and a partial volume with a working medium; and
a plurality of volume limiting elements which limit the at least one volume and which are configured such that one or more passages allow outflow of a maximum of a predetermined partial quantity of the liquid quantity during one or more of a compression period, an expansion period, or a displacement period,
wherein the liquid quantity performs a rotation about an axis of rotation during one or more of the compression period, the expansion period, or the displacement period,
wherein the plurality of volume limiting elements are additionally configured to prevent an annular flow of the liquid quantity about the axis of rotation, and
wherein the at least one volume is changeable in terms of its overall size during one or more of the compression period, the expansion period, or the displacement period by displacement of at least one of the plurality of volume limiting elements.

2. The device according to claim 1, wherein the device comprises at least two volumes, each volume of the at least two volumes comprising at least one partial volume of the working medium and liquid quantities, wherein the at least two volumes are each limited by the plurality of volume limiting elements so that liquid quantities of different volumes cannot mix to a maximum of the predetermined partial quantity.

3. The device according to claim 1, wherein the predetermined partial quantity is 5% or 10% or 15%.

4. The device according to claim 1, wherein at least one first volume limiting element of the plurality of volume limiting elements is to perform a rotational motion in a housing which comprises the at least one volume, wherein an axis of rotation of the at least one first volume limiting element differs from a central axis of the housing.

5. The device according to claim 1, wherein a first volume limiting element of the plurality of volume limiting elements comprises movable limiting elements configured to periodically change position relative to the first volume limiting element during rotation of the first volume limiting element.

6. The device according to claim 1, wherein a first volume limiting element of the plurality of volume limiting elements is configured to perform a motion comprising a first rotational motion about a first axis and a second rotational motion about a second axis.

7. The device according to claim 1, wherein a first volume limiting element of the plurality of volume limiting elements is configured to perform a rotational motion, a rotational speed of which has a constant ratio to a rotational motion of a housing.

8. The device according to claim 1,
where at least one first volume limiting element of the plurality of volume limiting elements comprises a piston or a hollow piston which is configured to perform a rotational motion that is overlaid with a periodic translational motion.

9. The device according to claim 1, wherein the liquid quantity is to move due to inertial forces or due to motion of at least one volume limiting element of the plurality of volume limiting elements in the at least one volume relative to other volume limiting elements of the plurality of volume limiting elements and changes a size of the partial volume.

10. The device according to claim 1, further comprising a plurality of heat transfer elements that are to periodically immerse into and out of the liquid in the liquid quantity disposed in the volume, wherein the plurality of heat transfer elements comprise one or more of a plate, a mesh, or a rod.

11. A thermoelectric converter comprising:
at least one volume that comprises a liquid quantity of a liquid and a partial volume with a working medium; and
a plurality of volume limiting elements which limit the at least one volume and which are configured such that one or more passages allow outflow of a maximum of a predetermined partial quantity of the liquid quantity during one or more of a compression period, an expansion period, or a displacement period,
wherein the liquid quantity performs a rotation about an axis of rotation during one or more of the compression period, the expansion period, or the displacement period,
wherein the plurality of volume limiting elements are additionally configured to prevent an annular flow of the liquid quantity about the axis of rotation, and
wherein the at least one volume is changeable in terms of its overall size during one or more of the compression period, the expansion period, or the displacement period by displacement of at least one of the plurality of volume limiting elements.

12. The thermoelectric converter according to claim 11, configured to implement a thermodynamic cyclic process comprising one or more of a Stirling process, an Ericsson process, a Clausius-Rankine process, or a modified Stirling process in which one or more of condensation or evaporation of a component of the working medium or liquid takes place in addition to compression and expansion or displacement of the working medium.

13. The thermoelectric converter according to claim 11, wherein at least one first volume limiting element of the plurality of volume limiting elements is to perform a rotational motion in a housing which comprises the at least one volume, wherein an axis of rotation of the at least one first volume limiting element differs from a central axis of the housing,
wherein the housing is mounted to be freely rotatable about the central axis of the housing.

14. A method for operating a thermoelectric converter, the method comprising:
rotating a liquid quantity about an axis of rotation of the thermoelectric converter during one or more of a compression period, an expansion period, or a displacement period, wherein at least one volume of the thermoelectric converter comprises the liquid quantity and a partial volume with a working medium; and
changing an overall size of at least one volume of the thermoelectric converter during one or more of the compression period, the expansion period, or the displacement period by displacement of at least one of a plurality of volume limiting elements of the thermoelectric converter, wherein the plurality of volume limiting elements limit the at least one volume and are configured such that one or more passages allow outflow of a maximum of a predetermined partial quantity of the liquid quantity during one or more of the compression period, the expansion period, or the displacement period, and wherein the plurality of volume limiting elements are additionally configured to prevent an annular flow of the liquid quantity about the axis of rotation.

15. The method according to claim 14, wherein the plurality of volume limiting elements are controlled such that during compression of the working medium the working medium is condensed at least in part and vaporized during a subsequent expansion.

16. The device according to claim 1, wherein at least one first volume limiting element of the plurality of volume limiting elements is to perform a first rotational motion and at least one second volume limiting element performs a second rotational motion, wherein a first axis of rotation of the first rotational motion and a second axis of rotation of the second rotational motion differ from each other.

17. The thermoelectric converter according to claim 11, wherein at least one first volume limiting element of the plurality of volume limiting elements is to perform a first rotational motion and at least one second volume limiting element is to perform a second rotational motion, wherein a first axis of rotation of the first rotational motion and a second axis of rotation of the second rotational motion differ from each other.

18. The thermoelectric converter according to claim 11, wherein the thermoelectric converter comprises at least two volumes, each volume of the at least two volumes comprising at least on partial volume of the working medium and liquid quantities, wherein the at least two volumes are each limited by the plurality of volume limiting elements so that liquid quantities of different volumes cannot mix to a maximum of the predetermined partial quantity.

19. The method of claim 14, further comprising:
rotating a first volume limiting element of the plurality of volume limiting elements in a housing which comprises the at least one volume, wherein an axis of rotation of the first volume limiting element differs from a central axis of the housing, and wherein the housing is mounted to be freely rotatable about the central axis of the housing.

20. The method of claim 14, further comprising:
rotating a first volume limiting element of the plurality of volume limiting elements; and
rotating a second volume limiting element of the plurality of volume limiting elements, wherein a first axis of rotation of the first volume limiting element and a second axis of rotation of the second volume limiting element differ from each other.
